(19) United States
(12) Patent Application Publication
(10) Pub. No.: US 2008/0211037 A1
(43) Pub. Date: Sep. 4, 2008

(54) Semiconductor Device and Method of Forming Isolation Layer Thereof

(75) Inventor: Chan Sun Hyun, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/962,722

(22) Filed: Dec. 21, 2007

(30) Foreign Application Priority Data
Jan. 4, 2007 (KR) 10-2007-0001057

(51) Int. Cl. H01L 21/76; H01L 27/10

(52) U.S. Cl. 257/396; 438/426; 257/E27.07; 257/E21.546

(57) ABSTRACT

A method of forming an isolation layer of a semiconductor device includes the steps of forming a gate insulating layer and a conductive layer on an active area of a semiconductor substrate; forming a spacer layer on side walls of the conductive layer; forming a trench on the semiconductor substrate between the spacer layer-covered side walls; removing the spacer layer to form a step on an upper edge of the trench; and forming a liner insulating layer on the trench. The method makes it possible to solve problems caused by impurities present in material with which the trench is gap-filled or present in etchants used in an etch-back process.

### CROSS-REFERENCE TO RELATED APPLICATION

The priority of Korean patent application No. 2007-1057 filed Jan. 4, 2007, the disclosure of which is incorporated herein by reference in its entirety, is claimed.

### BACKGROUND OF THE INVENTION

1. Field of the Disclosure

The invention relates to a semiconductor device and a method of forming an isolation layer thereof.

2. Brief Description of Related Technology

Recently, there has been an increased demand for flash memory devices capable of being electrically programmed and erased, and not needing a refresh function by which the data is periodically re-written. Here, “program” refers to an operation for writing data in a memory cell, and “erase” refers to an operation for removing the data written in the memory cell.

In a NAND flash memory device, which is one kind of such flash memory devices, a plurality of memory cells are connected to each other in series to form one string for a high integration of the memory device. Unlike a NOR-type flash memory device, the NAND flash memory device is the memory device that reads information sequentially. The program and erase operations of the NAND flash memory device are performed by implanting electrons into a floating gate or discharging electrons from the floating gate in a Fowler-Nordheim (F-N) tunneling manner.

NAND flash memory devices, benefit from a reliable memory cell. In particular, the data retention characteristic of the memory cell becomes the important problem. In the cycling process in which the F-N tunneling operation is repeatedly performed for the program and erase operations, however, electrons are trapped in a tunnel oxide layer of the memory cell. As a result, a threshold voltage of the memory cell is shifted so that the memory device erroneously recognizes the data stored in the original memory cell during the data reading process. Hence, reliability of the memory cell is reduced.

To prevent the threshold voltage from shifting, a method has been proposed that includes controlling a bias voltage when the program and erase operations are performed and reducing sufficiently an erasing voltage below a verifying voltage. However, the above method presents the problem that the threshold voltage is increased as much as an increase of the bias voltage so that the threshold voltage is shifted. Another method proposed for preventing the threshold voltage from shifting includes decreasing a thickness of the tunnel oxide layer to reduce the amount of electrons trapped in the tunnel oxide layer during the F-N tunneling operation. This method, however, is limited by an influence of a radical data retention characteristic problem or a read disturbance problem.

### SUMMARY OF THE INVENTION

The present invention improves characteristics of a tunnel oxide layer to minimize shifting of the threshold voltage of a memory cell, ordinarily caused by a cycling, and can enhance data retention characteristics of the memory cell by minimizing threshold voltage shifting. The present invention, therefore, can enhance the reliability of memory cells.

A method of forming an isolation layer of a semiconductor device according to one embodiment of the present invention includes forming a gate insulating layer and a conductive layer on an active area of a semiconductor substrate, forming a spacer layer on side walls of the conductive layer, forming a trench on the semiconductor substrate between the spacer layer-covered side walls, removing the spacer layer to form a step on an upper edge of the trench, and forming a liner insulating layer on the trench.

A semiconductor device according to the embodiment of the present invention includes a gate insulating layer formed on an active area of a semiconductor substrate, a conductive layer formed on the gate insulating layer, a trench formed on an isolation area of the semiconductor substrate, and a liner insulating layer formed on side walls of the conductor layer, the gate insulating layer, and the trench. The trench has steps formed on an upper edge adjacent to the gate insulating layer. The liner insulating layer formed on the side walls of the gate insulating layer has a thickness greater than the liner insulating layer formed on the side walls of the conductive layer.

Additional features of the invention may become apparent to those skilled in the art from a review of the following detailed description, taken in conjunction with the drawing figures and the appended claims.

### BRIEF DESCRIPTION OF THE DRAWINGS

For a more complete understanding of the disclosure reference should be made to the following detailed description, taken in conjunction with the accompanying drawings wherein:

FIGS. 1A to 1F are sectional views of a semiconductor device, illustrating the device and a method of forming an isolation layer thereof according to an embodiment of the invention.

While the disclosed device and method are susceptible of embodiments in various forms, there are illustrated in the drawings (and will hereafter be described) specific embodiments of the invention, with the understanding that the disclosure is intended to be illustrative, and is not intended to limit the invention to the specific embodiments described and illustrated herein.

### DESCRIPTION OF SPECIFIC EMBODIMENTS

A method of forming an isolation layer of a semiconductor device includes forming a gate insulating layer and a conductive layer on an active area of a semiconductor substrate, forming a spacer layer on side walls of the conductive layer, forming a trench on the semiconductor substrate between the spacer layer-covered side walls, removing the spacer layer to form a step on an upper edge of the trench, and forming a liner insulating layer on the trench.

A semiconductor device includes a gate insulating layer formed on an active area of a semiconductor substrate, a conductive layer formed on the gate insulating layer, a trench formed on an isolation area of the semiconductor substrate, and a liner insulating layer formed on side walls of the conductive layer, the gate insulating layer, and the trench. The trench has steps formed on an upper edge adjacent to the gate insulating layer. The liner insulating layer formed on the side walls of the gate insulating layer has a thickness greater than the liner insulating layer formed on the side walls of the conductive layer.

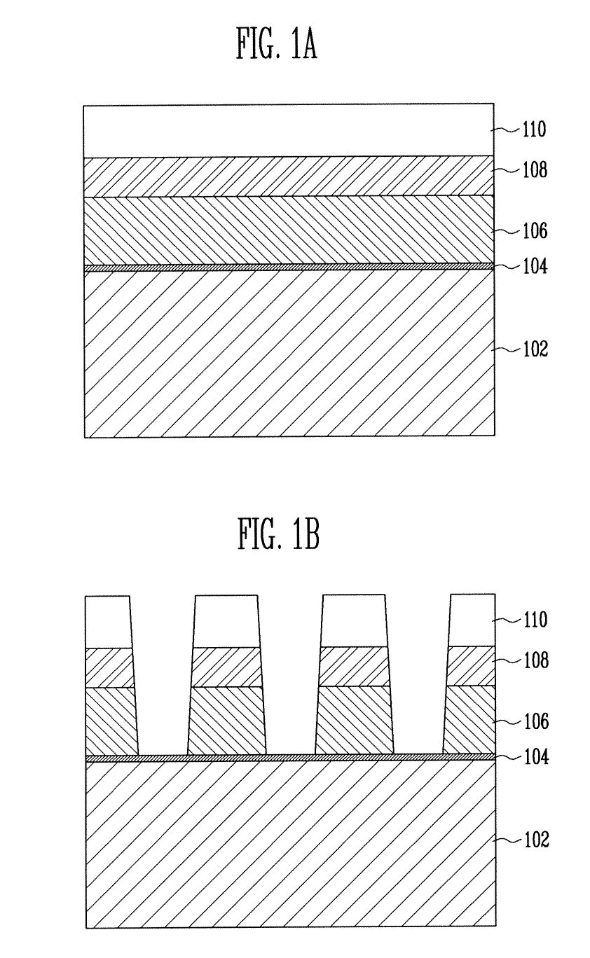

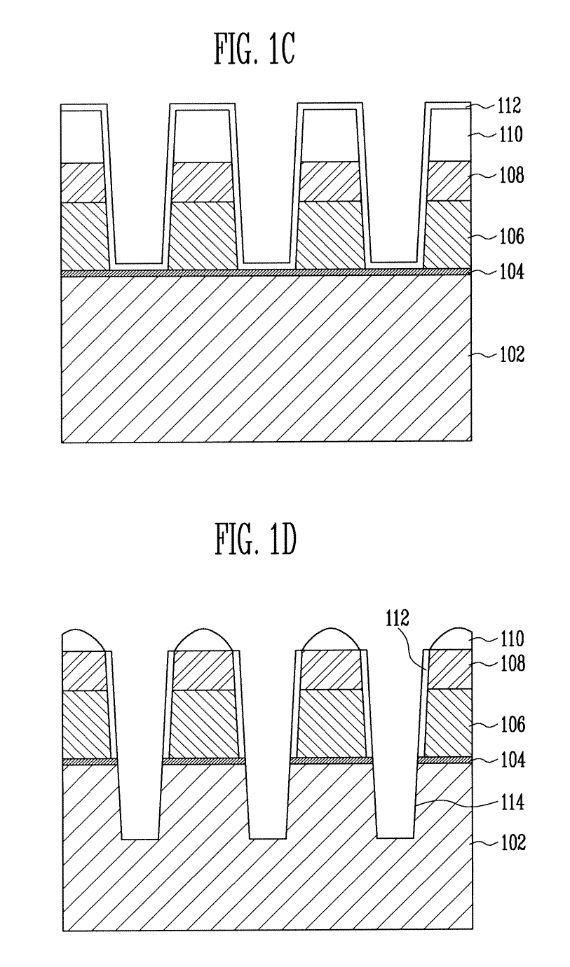

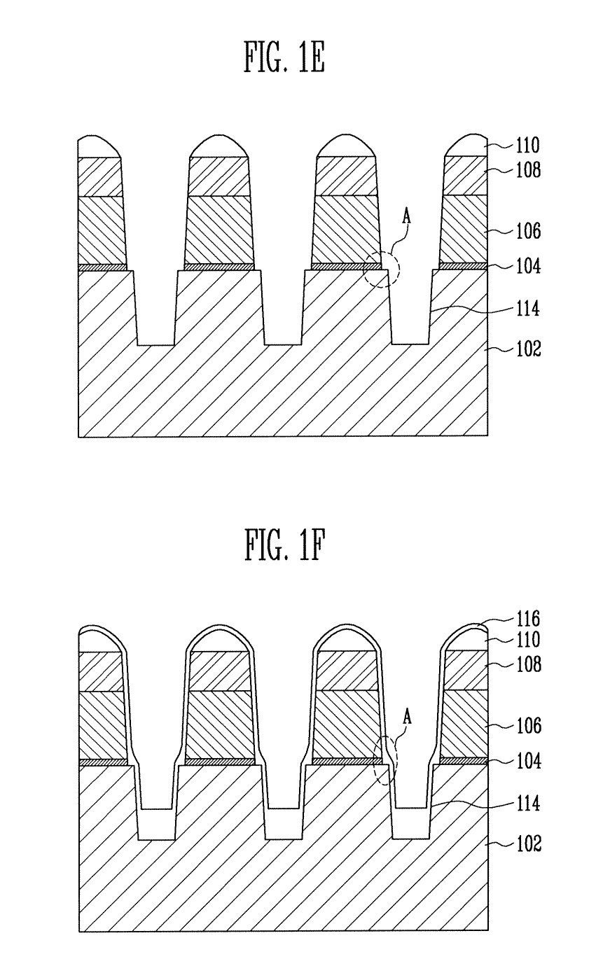

Referring to the drawing figures wherein like reference numbers refer to the same or similar elements in the various figures, in FIG. 1A a screen oxide layer (not shown) is formed on a semiconductor substrate 102, and a well ion implanting process or a threshold voltage ion implanting process is performed for the semiconductor substrate 102. Here, the well ion implanting process forms a well region (not shown) on the semiconductor substrate 102, and the threshold voltage ion implanting process adjusts a threshold voltage of the semiconductor device, such as a transistor. The screen oxide layer (not shown) prevents a surface of the semiconductor substrate 102 from being damaged during the well ion implanting process or the threshold voltage ion implanting process. Due to the above process, the well region (not shown) is formed on the semiconductor substrate 102 and can have the triple structure.

With continued reference to FIG. 1A, the screen oxide layer is removed, and a gate insulating layer 104 and a conductive layer 106 are then formed on the semiconductor substrate 102. The gate insulating layer 104 is used as a tunnel insulating layer and can be formed of an oxide layer. The conductive layer 106 can be formed from polysilicon. In addition, a nitride layer 108 and an oxide layer 110, acting as a hard mask, are formed on the conductive layer 106.

Referring to FIG. 1B, photoresist patterns (not shown) are formed on the oxide layer 110. The oxide layer 110 and the nitride layer 108 are then patterned through an etching process utilizing the photoresist pattern (not shown) to form gate mask patterns. The conductive layer 106 is patterned by a gate etching process in which the patterned oxide layer 110 and the patterned nitride layer 108 are used as the gate mask patterns. At this time, the gate insulating layer 104 is partially exposed. Thereafter, the photoresist pattern (not shown) is removed.

Referring to FIG. 1C, a spacer layer 112 is formed on the oxide layer 110, the nitride layer 108, and the conductive layer 106, which are patterned through the above processes, and on the exposed gate insulating layer 104. Preferably the spacer layer 112 is formed along a side wall and an upper surface of the patterned oxide layer 110, and side walls of the patterned nitride layer 108 and conductive layer 106. The spacer layer 112 preferably has a thickness by which shapes of the oxide layer 110, the nitride layer 108 and the conductive layer 106 can be maintained. More preferably the spacer layer 112 has a thickness of 50 [symbol] to 100 [symbol] . Preferably the spacer layer 112 is formed of a low pressure tetra ethyl ortho silicate (LP-TEOS) oxide layer, which is easily removed in a subsequent etching process.

Referring to FIG. 1D, an anisotropic etching process is performed to ensure that the spacer layer 112 remains on only the side walls of the conductive layer 106 and the nitride layer 108. Preferably carbon tetrafluoride (CF₄) gas, or mixed gas of carbon tetrafluoride (CF₄) gas and trifluoromethane (CHF₃) gas is utilized in the anisotropic etching process to etch the oxide layer 110. In the meantime, while the spacer layer 112 is removed during the anisotropic etching process, the gate insulating layer 104 disposed between the patterned conductive layer 106 and the substrate 102 can be removed simultaneously. Further, a portion of the oxide layer 110 can be etched along with the above layers. Due to the above process, the gate insulating layer 104, the conductive layer 106 and the spacer layer 112 are formed on only an active area of the semiconductor substrate 102.

Subsequently, the exposed semiconductor substrate 102 is etched, preferably dry-etched, in-situ to form a trench 114 on an isolation area of the semiconductor substrate 102 and between the spacer layer-covered side walls. Preferably the dry etching process utilizes an etching gas obtained by mixing hydrogen bromide (HBr) gas, chlorine (Cl₂) gas, oxygen (O₂) gas, and hydrogen (H₂) gas to etch the semiconductor substrate 102.

Referring to FIG. 1E, the spacer layer 112 (see FIG. 1D) remaining on the conductive layer 106 and the nitride layer 108 is etched and removed. A wet etching process, utilizing buffered oxide etchant (BOE) or hydrofluoric (HF) acid as etchant, can be performed to etch the spacer layer 112. At this time, the oxide layer 110 and the gate insulating layer 104 may also be etched. As a result, step portions with a height corresponding to a thickness of the removed spacer layer 112 (see FIG. 1D) are formed at both end portions (A in FIG. 1E) of the active area.

Referring to FIG. 1F, an oxidation process is performed for a side wall of the trench 114 to form a side wall oxide layer (not shown) on a side wall of the trench 114. The side wall oxide layer can compensate for defects of the side wall of the trench 114 formed when the trench 114 is formed and alleviate stress. In addition, a liner oxide layer 116 is formed on the entire structure including the trench 114. The liner oxide layer 116 is formed for filling the trench 114 with the insulating material during a subsequent process. Preferably, the liner layer 116 can be formed of a high density plasma (HDP) oxide layer. The liner oxide layer 116 should be sufficiently thick to allow the trench 114 to not fill completely, and to maintain a shape of the trench 114. In particular, due to the step formed at the end portions (A in FIG. 1E) of the active area in the aforementioned process, the liner oxide layer 116 formed on a side wall of the gate insulating layer 104 is thicker than that formed on a side wall of the conductive layer 106 on the step portions A.

Subsequently, although not shown in the drawings, an insulating layer, for example, a HDP oxide layer or a spin on glass (SOG) oxide layer is formed on the entire structure, including the trench 114, to gap-fill the trench 114, and an etch-back process is then performed to form an isolation layer.

If a thickness of the liner oxide layer formed on a side wall of the gate insulating layer 104 is thin, impurities such as hydrogen (H), nitrogen (N) and the like contained in the insulating layer with which the trench 114 is gap-filled, can undesirably penetrate into the gate insulating layer 104, or etchant used in the etch-back process can undesirably penetrate into the gate insulating layer 104.

According to the invention, however, the liner oxide layer 116 formed on a side wall of the gate insulating layer 104 has a thickness greater than the thickness of the liner oxide layer formed on the conductive layer 106, and it is therefore possible to prevent the impurities or etchant from penetrating into the gate insulating layer 104. Consequently, damage of the gate insulating layer 104 can be prevented. In addition, because a width of an upper portion of the trench 114 becomes large due to the step formed at the end portions (A in FIG. 1E) of the active area of the semiconductor substrate 102, the trench 114 can be more easily gap-filled with the insulating layer in the subsequent process.

According to the invention, the liner oxide layer formed on a side wall of the insulating layer 104 is sufficiently thick to prevent damage to the insulating layer, which damage may be caused by the impurities contained in material used for gap-filling the trench or etchant used in the etch-back process As a result, the invention can avoid or prevent problems associated with prior art methods and (undesirably threshold voltage shifting and trapped electrons in the tunnel oxide layer).

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of forming an isolation layer of a semiconductor device, the method comprising the steps of:
(a) forming a gate insulating layer and a conductive layer on an active area of a semiconductor substrate;
(b) forming a spacer layer on side walls of the conductive layer;
(c) forming a trench on the semiconductor substrate between the spacer layer-covered side walls;
(d) removing the spacer layer to form a step on an upper edge of the trench; and,
(e) forming a liner insulating layer on the trench.

2. The method of claim 1, wherein in step (e) the liner oxide layer formed on both side walls of the gate insulating layer is thicker than that formed on a side wall of the conductive layer.

3. The method of claim 1, wherein spacer layer forming step (b) comprises:
(i) forming a gate mask pattern;
(ii) pattering the conductive layer with the gate mask pattern;
(iii) forming the spacer layer on an upper surface and side walls of the gate mask pattern and side walls of the patterned conductive layer; and,
(iv) anisotropic etching the spacer layer to allow the spacer layer to remain on the side walls of the conductive layer.

4. The method of claim 1, wherein the spacer layer is formed of an oxide layer.

5. The method of claim 1, wherein the spacer layer is formed of a low pressure tetra ethyl ortho silicate oxide layer.

6. The method of claim 3, wherein anisotropic etching is performed utilizing as an etchant carbon tetrafluoride (CF₄) gas, or a mixed gas of carbon tetrafluoride (CF₄) gas and trifluoromethane (CHF₃) gas.

7. The method of claim 3, wherein the spacer layer remains on side walls of the gate mask pattern.

8. The method of claim 3, wherein the anisotropic etching step (iv) further comprises removing the exposed gate insulating layer.

9. The method of claim 1, wherein the trench is formed in in-situ with the spacer layer.

10. The method of claim 1, wherein the trench is formed by a dry etching process.

11. The method of claim 10, wherein the dry etching process is performed utilizing as an etchant a mixed gas of hydrogen bromide (HBr) gas, chlorine (Cl₂) gas, oxygen (O₂) gas, and hydrogen (H₂) gas.

12. The method of claim 1, wherein step (d) comprises a wet etching process to remove the spacer layer.

13. The method of claim 12, wherein the wet etching process is performed utilizing as an etchant buffered oxide etchant (BOE) or hydrofluoric (HF) acid.

14. The method of claim 1, wherein the spacer layer has a thickness of 50 Å to 100 Å.

15. The method of claim 1, further comprising the step of
(f) forming an insulating layer on the liner oxide layer to gap-fill the trench.

15. A semiconductor device comprising:
(a) a gate insulating layer formed on an active area of a semiconductor substrate;
(b) a conductive layer formed on the gate insulating layer;
(c) a trench formed on an isolation area of the semiconductor substrate, the trench having steps formed on an upper edge adjacent to the gate insulating layer; and,
(d) a liner insulating layer formed on side walls of the conductive layer, the gate insulating layer, and the trench, the liner insulating layer formed on the side walls of the gate insulating layer having a thickness greater than the liner insulating layer formed on the side walls of the conductive layer.
